(19) United States
(12) Patent Application Publication
(10) Pub. No.: US 2023/0413524 A1
(43) Pub. Date: Dec. 21, 2023

(54) SEMICONDUCTOR DEVICE INCLUDING A FORROELECTRIC TRANSISTOR

(71) Applicant: SAMSUNG ELECTRONICS CO., LTD., SUWON-SI (KR)

(72) Inventor: KIJOON KIM, SUWON-SI (KR)

(21) Appl. No.: 18/186,849

(22) Filed: Mar. 20, 2023

(30) Foreign Application Priority Data
Jun. 16, 2022 (KR) 10-2022-0073761

(51) Int. Cl. H10B 12/00; H01L 29/78

(52) U.S. Cl. CPC H10B 12/315; H10B 12/482; H10B 12/488; H01L 29/78391

(57) ABSTRACT

A semiconductor device includes bit lines arranged on a substrate and extending in a first horizontal direction; channel layers respectively arranged on the plurality of bit lines; word lines respectively arranged on the plurality of channel layers, and extending in a second horizontal direction; and ferroelectric layers arranged between the plurality of channel layers and the plurality of word lines, wherein the plurality of ferroelectric layers comprise a base dielectric layer and a nanoparticle, the nanoparticle dispersed and arranged in the base dielectric layer, respectively, the nanoparticle has a core-shell structure including a core and a shell.

### CROSS-REFERENCE TO RELATED APPLICATION

This application claims priority under 35 U.S.C. § 119 to Korean Patent Application No. 10-2022-0073761, filed on Jun. 16, 2022, in the Korean Intellectual Property Office, the disclosure of which is incorporated by reference herein in its entirety.

### TECHNICAL FIELD

The inventive concept relates to a semiconductor device, and more particularly, to a semiconductor device including a ferroelectric transistor.

### DISCUSSION OF THE RELATED ART

As semiconductor devices are downscaled, the size of an individual microcircuit pattern for implementing the semiconductor devices is further reduced. In particular, as the height of a capacitor included in a dynamic random-access memory (DRAM) device increases, the difficulty level of a capacitor forming process increases, and a refresh is required to solve a leakage current through the capacitor. Accordingly, there are limitations in increasing the degree of integration of DRAM devices and in applying downscaling to other devices requiring low-power operations.

### SUMMARY

According to embodiments of the inventive concept, a semiconductor device includes a plurality of bit lines arranged on a substrate and extending in a first horizontal direction; a plurality of channel layers respectively arranged on the plurality of bit lines; a plurality of word lines respectively arranged on the plurality of channel layers, and extending in a second horizontal direction; and a plurality of ferroelectric layers arranged between the plurality of channel layers and the plurality of word lines. The plurality of ferroelectric layers include a base dielectric layer and a nanoparticle, the nanoparticle dispersed and arranged in the base dielectric layer, respectively, the nanoparticle having a core-shell structure including a core and a shell, the core including a portion formed inside the nanoparticle and having a particular volume, and the shell including a portion corresponding to the nanoparticle except for the core and at least partially surrounds the core.

According to embodiments of the inventive concept, a semiconductor device includes a plurality of bit lines arranged on a substrate and extending in a first horizontal direction, a plurality of mold insulating layers respectively arranged on the plurality of bit lines, one or more of the plurality of mold insulating layers including a plurality of openings extending in a second horizontal direction substantially vertical to the first horizontal direction, a first cell transistor arranged on a first sidewall of an opening of the plurality of openings, and a second cell transistor arranged on a second sidewall of the opening. The first cell transistor includes a first channel layer arranged on the first sidewall of the opening, a first ferroelectric material arranged on the first channel layer, and a first word line arranged on the first ferroelectric material and extending in the second horizontal direction. The second cell transistor includes a second channel layer arranged on the second sidewall of the opening, a second ferroelectric material arranged on the second channel layer, and a second word line arranged on the second ferroelectric material and extending in the second horizontal direction. The first ferroelectric material and the second ferroelectric material each includes a base dielectric layer and nanoparticles, the nanoparticles having a core-shell structure including a core and a shell and the nanoparticles distributed and arranged in the base dielectric layer. The core includes a center of the nano particle, and the shell includes a portion except for the core in the nano particle and at least partially surrounds the core.

According to embodiments of the inventive concept, a semiconductor device includes a bit line arranged on a substrate and extending in a first horizontal direction, a channel layer including a first vertical extension portion arranged on the bit line and extending in a vertical direction substantially vertical to an upper surface of the substrate, a second vertical extension portion spaced apart from the first vertical extension portion and extending in the vertical direction, and a horizontal extension portion connected to bottom portions of the first vertical extension portion and the second vertical extension portion and extending in the first horizontal direction, a gate insulating layer arranged on the first vertical extension portion and the second vertical extension portion, a ferroelectric layer arranged on the gate insulating layer, and a plurality of word lines arranged on the ferroelectric layer and extending in a second horizontal direction substantially vertical to the first horizontal direction, the plurality of word lines including first word lines arranged on the first vertical extension portion with the gate insulating layer and the ferroelectric layer arranged therebetween and second word lines arranged on the second vertical extension portion with the gate insulating layer and the ferroelectric layer arranged therebetween. The ferroelectric layer includes a base dielectric layer and a nanoparticle, the nanoparticle dispersed and arranged in the base dielectric layer. The nanoparticle has a core-shell structure. The nanoparticle and the core have a spherical shape having a substantially concentric cross-section. The hell includes a portion corresponding to the nanoparticle except for the core and at least partially surrounds the core.

### BRIEF DESCRIPTION OF THE DRAWINGS

Embodiments will be more clearly understood from the following detailed description taken in conjunction with the accompanying drawings in which:

FIG. 1 is a layout diagram of a semiconductor device according to an embodiment;

FIG. 2 is an detailed layout diagram of a cell array area in FIG. 1;

FIG. 3 is a cross-sectional view taken along line A1-A1′ in FIG. 2;

FIG. 4 is a detailed cross-sectional view of region P in FIG. 3;

FIG. 5 is a detailed cross-sectional view of region Q in FIG. 4;

FIG. 6 is a detailed cross-sectional view of region R in FIG. 5;

FIGS. 7A and 7B are schematic diagrams of microstructures of partial regions of a comparative example and an embodiment for explaining effects of a semiconductor device, respectively, according to embodiments;

FIGS. 8 and 9 are flowcharts illustrating a manufacturing method of a semiconductor device, according to embodiments;

FIGS. 10A through 10D are detailed cross-sectional views of some regions of a semiconductor device, according to embodiments;

FIG. 11 is a cross-sectional view of a semiconductor device according to embodiments;

FIG. 12A is a perspective view of a semiconductor device according to embodiments;

FIG. 12B is a cross-sectional view taken along line A2-A2′ in FIG. 12A;

FIG. 12C is a detailed cross-sectional view of region Q in FIG. 12B;

FIG. 12D is a detailed cross-sectional view of region R in FIG. 12C;

FIG. 13A is a layout diagram of a semiconductor device according to embodiments;

FIG. 13B is a cross-sectional view taken along line A3-A3′ in FIG. 13A;

FIG. 13C is a detailed cross-sectional view of region Q in FIG. 13B;

FIG. 13D is a detailed cross-sectional view of region R in FIG. 13C;

FIG. 14A is a perspective view of a semiconductor device according to embodiments;

FIG. 14B is a detailed cross-sectional view of region Q in FIG. 14A; and

FIG. 14C is a detailed cross-sectional view of region Q in FIG. 14B.

### DETAILED DESCRIPTION OF THE EMBODIMENTS

For proper understanding of configurations and effects of the inventive concept, some embodiments of the inventive concept are described with reference to the accompanying drawings. However, the inventive concept is not necessarily limited to the embodiments disclosed below, but may be implemented in various forms and various changes may be applied thereto. Descriptions of the inventive concept are provided to disclose the inventive concept, and to inform the scope of the inventive concept to those of skill in the art. In the accompanying drawings, the components are enlarged in size than the actual size for convenience of explanation, and the size ratio of each component may be exaggerated or reduced.

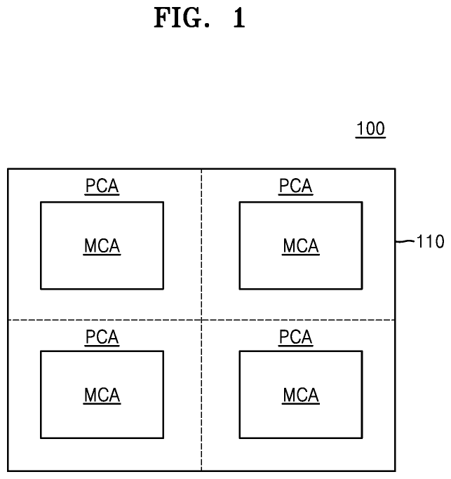

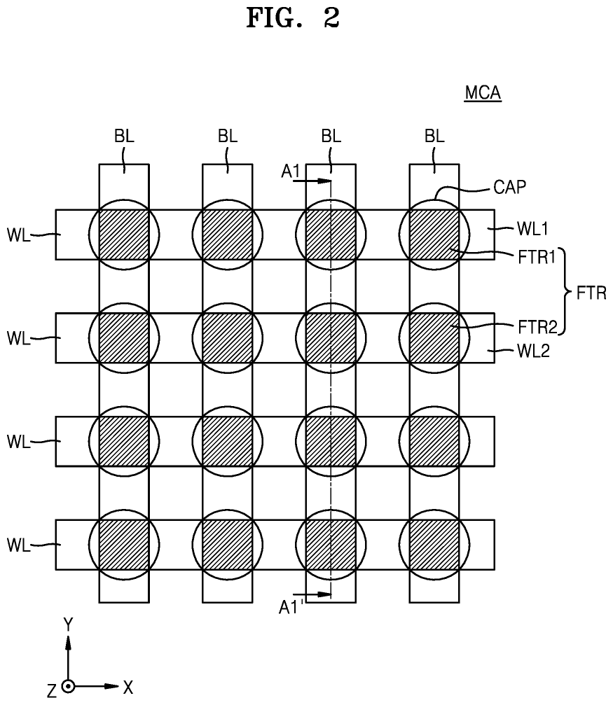

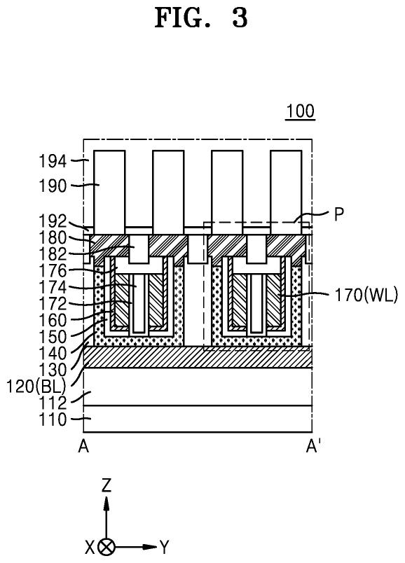

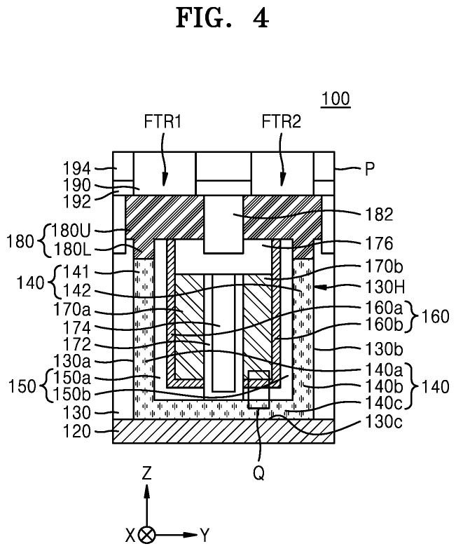

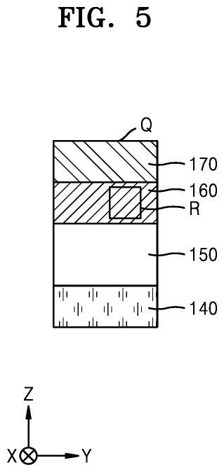

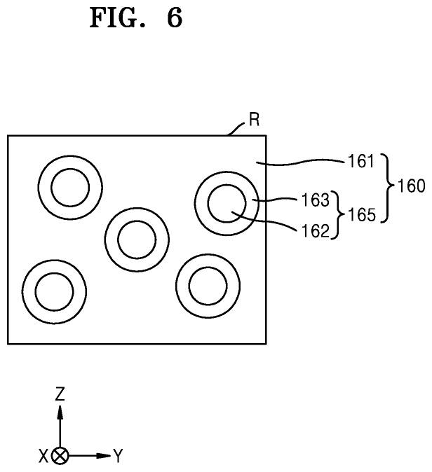

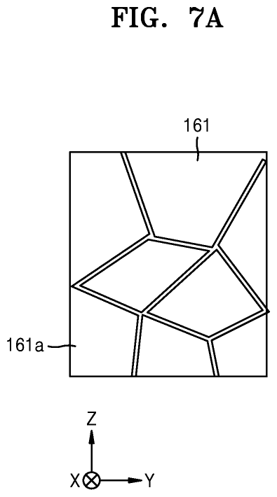

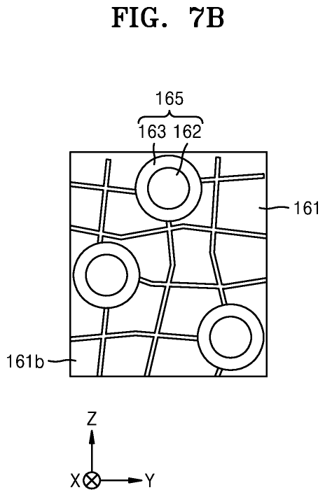

FIG. 1 is a layout diagram of a semiconductor device 100 according to embodiments. FIG. 2 is a detailed layout diagram of a cell array area MCA in FIG. 1. FIG. 3 is a cross-sectional view taken along line A1-A1′ in FIG. 2. FIG. 4 is a detailed cross-sectional view of region P in FIG. 3. FIG. 5 is a detailed cross-sectional view of region Q in FIG. 4. FIG. 6 is a detailed cross-sectional view of region R in FIG. 5. FIGS. 7A and 7B are schematic diagrams of microstructures of partial regions of a comparative example and an embodiment for explaining effects of a semiconductor device, respectively, according to embodiments.

Referring to FIGS. 1 through 7B, the semiconductor device 100 may include a substrate 110 including the cell array area MCA and a periphery circuit area PCA. In some embodiments, the cell array area MCA may include a memory cell area of a dynamic random-access memory (DRAM) device, and the periphery circuit area PCA may include a core area or a periphery circuit area of the DRAM device. For example, the periphery circuit area PCA may include a periphery circuit transistor for transmitting signals and/or power to a memory cell array included in the cell array area MCA. In embodiments, the periphery circuit transistor may constitute various circuits, such as a command decoder, a control logic, an address buffer, a row decoder, a column decoder, a sense amplifier, and a data input/output circuit.

As illustrated in FIGS. 1 and 2, a plurality of word lines WL extending in a first horizontal direction X, and a plurality of bit lines BL extending in a second horizontal direction Y may be arranged on the cell array area MCA of a substrate 110. A plurality of ferroelectric transistors FTR may be arranged at intersections of the plurality of word lines WL and the plurality of bit lines BL. A plurality of capacitor structures CAP may be arranged respectively on the plurality of ferroelectric transistors FTR. The plurality of word lines WL may include a first word line WL1 and a second word line WL2 alternately arranged in the second horizontal direction Y, and the plurality of ferroelectric transistors FTR may include a first ferroelectric transistor FTR1 and a second ferroelectric transistor FTR2 alternately arranged in the second horizontal direction Y. The first ferroelectric transistor FTR1 may be arranged on the first word line WL1, and the second ferroelectric transistor FTR2 may be arranged on the second word line WL2. In some embodiments, the plurality of word lines WL are substantially equally spaced in the first horizontal direction X, and the plurality of bit lines BL are substantially equally spaced in the second horizontal direction Y. However, the inventive concept is not necessarily limited thereto, and the plurality of word lines WL and the plurality of bit lines BL may be unequally spaced, respectively.

The first ferroelectric transistor FTR1 and the second ferroelectric transistor FTR2 may have a mirror symmetrical structure with respect to each other. For example, the first ferroelectric transistor FTR1 and the second ferroelectric transistor FTR2 may have a mirror symmetrical structure. In some embodiments, a pair of neighboring ferroelectric transistors extending in the first horizontal direction X have mirror symmetrical structure with each other.

As illustrated in FIGS. 3 and 4, a lower insulating layer 112 may be arranged on the substrate 110. The substrate 110 may include silicon, for example, monocrystalline silicon, polycrystalline silicon, or amorphous silicon. In some embodiments, the substrate 110 may include at least one of Ge, SiGe, SiC, GaAs, InAs, and InP. In some embodiments, the substrate 110 may include a conductive area, for example, a sidewall doped with impurities, or a structure doped with impurities. The lower insulating layer 112 may include an oxide layer, a nitride layer, or a combination thereof.

A bit line 120 extending in the second horizontal direction Y may be arranged on the lower insulating layer 112. The lower insulating layer 112 may be arranged between the substrate 110 and the bit line 120 so that the bit line 120 has no contact with the substrate. The bit line 120 may correspond to the bit line BL in FIG. 2. In some embodiments, the bit line BL may include Ti, TiN, Ta, TaN, Mo, Ru, W, WN, TiSiN, WSiN, polysilicon, or a combination thereof. For example, the bit line BL may include a conductive layer and a conductive barrier arranged on upper and lower surfaces of the conductive layer, respectively. A bit line insulating layer extending in the second horizontal direction Y may be arranged on a sidewall of the bit line BL. For example, the bit line insulating layer may be formed to have the same height in the vertical direction Z as the bit line BL while filling a space between two adjacent bit lines BL in the second horizontal direction Y.

A mold insulating layer 130 may be arranged on an upper surface formed by the plurality of bit lines 120. A mold insulating layer 130 may include an opening 130H. The plurality of openings 130H may include a first sidewall 130a and a second sidewall 130b in parallel with each other, and the first sidewall 130a and the second sidewall 130b may be spaced apart from each other and extend in the first horizontal direction X. An upper surface of the bit line BL may be exposed to a bottom portion 130c of one or more of the plurality of openings 130H. The mold insulating layer 130 may include an oxide layer, a nitride layer, a low dielectric layer, or a combination thereof.

A plurality of channel layers 140 may be arranged on inner sidewalls of a plurality of openings 130H. The plurality of channel layers 140 may be arranged on the first sidewall 130a, the second sidewall 130b, and the bottom portion 130c of the plurality of openings 130H. The plurality of channel layers 140 may include a first vertical extension portion 140a arranged on the first sidewall 130a of the plurality of openings 130H, a second vertical extension portion 140b arranged on the second sidewall 130b of the plurality of openings 130H, and a horizontal extension portion 140c arranged on the bottom portion 130c of the plurality of openings 130H. The horizontal extension portion 140c of the channel layer 140 may be arranged on the bit line 120. For example, the first vertical extension portion 140a of the channel layer 140 may extend in a vertical direction Z on the first sidewall 130a of the plurality of openings 130H, the second vertical extension portion 140b may extend in the vertical direction Z on the second sidewall 130b of the plurality of openings 130H, and the horizontal extension portion 140c may extend in the second horizontal direction Y and may be connected to bottom portions of the first vertical extension portion 140a and the second vertical extension portion 140b. For example, one or more of the plurality of channel layers 140 may have a U-shaped vertical cross-section formed by the first vertical extension portion 140a, the second vertical extension portion 140b, and the horizontal extension portion 140c.

A first channel layer 141 of the first ferroelectric transistor FTR1 may include the first vertical extension portion 140a arranged on the first sidewall 130a and a portion of the horizontal extension portion 140c arranged on the bottom portion 130c, and a second channel layer 142 of the second ferroelectric transistor FTR2 may include the second vertical extension portion 140b arranged on the second sidewall 130b and the remainder of the horizontal extension portion 140c arranged on the bottom portion 130c. The first channel layer 141 of the first ferroelectric transistor FTR1 and the second channel layer 142 of the second ferroelectric transistor FTR2 may have a mirror symmetrical structure with respect to each other. For example, the first channel layer 141 and the second channel layer 142 may have a mirror symmetrical structure with respect to a center line between the first ferroelectric transistor FTR1 and the second ferroelectric transistor FTR2 extending in the first horizontal direction X. In particular, a portion of the horizontal extension portion 140c may contact an upper surface of the bit line 120 and may form a contact area shared by the first ferroelectric transistor FTR1 and the second ferroelectric transistor FTR2.

In some embodiments, a plurality of channel layers 140 may include an oxide semiconductor material. For example, the plurality of channel layers 140 may include a material having a bandgap greater than that of polysilicon, for example, a material having a bandgap greater than about 1.65 eV. In some embodiments, the plurality of channel layers 140 may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}SnO), gallium zinc tin oxide (GaₓZn_{y}Sn_{z}O), and zirconium zinc tin oxide (ZrₓZn_{y}Sn_{z}O). In some embodiments, the plurality of channel layers 140 may include a two-dimensional semiconductor material, and the two-dimensional semiconductor material may include graphene, a carbon nanotube, or a combination thereof. In some embodiments, the plurality of channel layers 140 may include Ti, TiN, Ta, TaN, W, WN, TiSiN, WSiN, polysilicon, or a combination thereof.

A gate insulating layer 150 may be arranged on the plurality of channel layers 140. In some embodiments, a gate insulating layer 150 may be arranged on outer sidewalls of the plurality of channel layers 140. For example, the gate insulating layer 150 may be conformally arranged on a sidewall of the first vertical extension portion 140a, a sidewall of the second vertical extension portion 140b, and an upper surface of the horizontal extension portion 140c of the plurality of channel layers 140.

In embodiments, the gate insulating layer 150 may include silicon oxide, silicon nitride, silicon oxynitride, a high-k material, or a combination thereof.

A ferroelectric layer 160 may be arranged on the gate insulating layer 150. In some embodiments, the gate insulating layer 150 is arranged between the channel layer 140 and the ferroelectric layer 160. In some embodiments, the gate insulating layer 150 forms an insulating area between channel layer 140 and the ferroelectric layer 160. In embodiments, the ferroelectric layer 160 may include a ferroelectric material, in which electrical dipole moments are aligned and spontaneous polarization is maintained.

The ferroelectric layer 160 may include a base dielectric layer 161 and a plurality of nanoparticles 165, the plurality of nanoparticles 165 dispersed and arranged in the base dielectric layer 161. A structure and material of the ferroelectric layer 160 are described in detail below with reference to FIGS. 6, 7A, and 7B.

A word line 170 may be arranged on the ferroelectric layer 160. The word line 170 may correspond to the word line WL in FIG. 2. In embodiments, the word line 170 may include Ti, TiN, Ta, TaN, Mo, Ru, W, WN, TiSiN, WSiN, polysilicon, or a combination thereof. The word line 170 may be arranged on sidewalls of the first vertical extension portion 140a and the second vertical extension portion 140b of the channel layer 140 with the gate insulating layer 150 and the ferroelectric layer 160 therebetween. For example, the word line 170 may be arranged the ferroelectric layer 160, and the gate insulating layer 150 may be arranged between the ferroelectric layer 160 and the channel layer 140. The word line 170 may include a first word line 170a arranged on the first sidewall 130a of the opening 130H of the mold insulating layer 130 with the channel layer 140, the gate insulating layer 150, and the ferroelectric layer 160 therebetween, and a second word line 170b arranged on the second sidewall 130b of the opening 130H of the mold insulating layer 130 with the channel layer 140, the gate insulating layer 150, and the ferroelectric layer 160 therebetween.

The first word line 170a and the second word line 170b may be apart from each other with an insulating layer therebetween. An insulating liner 172 may be arranged on sidewalls of two word lines (for example, 170a and 170b) spaced apart from each other in the opening 130H of the mold insulating layer 130, and a buried insulating layer 174 filling a space between two word lines (170a and 170b) apart from each other may be arranged on the insulating liner 172. The insulating liner 172 may be conformally arranged on sidewalls, facing each other, of two word lines WL (for example, the first word line WL1 and the second word line WL2), and may have an upper surface arranged on the same plane as the word line 170. For example, the upper surface of the insulating liner 172 may be at substantially the same height as the upper surface of the word line 170 in the vertical direction Z. For example, the insulating liner 172 may include silicon nitride, and the buried insulating layer 174 may include silicon oxide.

An upper insulating layer 176 may be arranged on the word line 170, the insulating liner 172, and the buried insulating layer 174 in the opening 130H. In some embodiments, the upper insulating layer 176 may be arranged to form contact with the upper surface of the word line 170 and the upper surface of the buried insulating layer 174. In some embodiments, the upper insulating layer 176 may be arranged to form contact with the ferroelectric layer 160. An upper surface of the upper insulating layer 176 may be arranged at the same level of height in the vertical direction Z as the mold insulating layer 130.

A landing pad 180 may be arranged on the upper insulating layer 156 to form contact with an upper surface of the channel layer 140. A landing pad insulating layer 158 at least partially surrounding the periphery of the landing pad 180 may be arranged on the mold insulating layer 130 and the upper insulating layer 176.

As illustrated in FIG. 4, in some embodiments, the landing pad 180 may have a T-shaped vertical cross-section. The landing pad 180 may include an upper portion 180U and a lower portion 180L. The upper portion 180U of the landing pad 180 may be referred to as a portion of the landing pad 180 arranged at a higher level than the upper surface of the mold insulating layer 130, and the lower portion 180L of the landing pad 180 may be referred to as a portion of the landing pad 180 arranged between the mold insulating layer 130 and the upper insulating layer 176. In embodiments, the landing pad 180 may include Ti, TiN, Ta, TaN, W, WN, TiSiN, WSiN, polysilicon, or a combination thereof.

A bottom surface of the lower portion 180L of the landing pad 180 may contact an upper surface of the channel layer 140, and both sidewalls of the lower portion 180L of the landing pad 180 may be aligned with both sidewalls of the channel layer 140. The bottom surface of the lower portion 180L of the landing pad 180 may be arranged at a higher level than an upper surface of the word line 170 in vertical direction Z, and a portion of sidewalls of the lower portion 180L of the landing pad 180 may be covered by the gate insulating layer 150.

An etch stop layer 192 may be arranged on the landing pad 180 and the landing pad insulating layer 182. A capacitor structure 190 may be arranged on the etch stop layer 192, and an interlayer insulating layer 194 may be arranged on the capacitor structure 190. In embodiments, the capacitor structure 190 may include a lower electrode, a capacitor dielectric layer, and an upper electrode. However, the inventive concept is not necessarily limited thereto, and other types of memory storage components may be arranged in place of the capacitor structure 190. For example, the memory storage component may include a variable resistance memory component, a phase change memory component, a magnetic memory component, etc.

As illustrated in the detailed view of FIG. 6, the ferroelectric layer 160 may include the base dielectric layer 161 and the plurality of nanoparticles 165, the plurality of nanoparticles 165 dispersed and arranged in the base dielectric layer 161.

The base dielectric layer 161 may include a ferroelectric material. In some embodiments, the base dielectric layer 161 may include a hafnium-based oxide with an orthorhombic crystal structure, and the hafnium-based oxide may include, for example, an o-phase having an orthorhombic crystal structure. In embodiments, the base dielectric layer 161 may include hafnium oxide (HfO₂), and may further include impurities of metal elements. For example, the base dielectric layer 161 may include a ferroelectric material having a chemical formula of HfₓM₁₋ₓO_{y} (0<x<1, 2≤y≤4, and M includes at least one of Zr, Si, Al, Y, Gd, La, Sc, and Sr). In some embodiments, the base dielectric layer 161 may include HfₓZr₁₋ₓO_{y} (0.2≤x≤0.8, 2≤y≤4).

The plurality of nanoparticles 165 may have a core 162-shell 163 structure. The core 162 may include a portion formed in the nanoparticles 165 and having a particular volume, and the shell 163 may include a portion corresponding to the nanoparticles 165 except for the core 162, and may have a shape at least partially surrounding the core 162. As illustrated, the plurality of nanoparticles 165 and the core 162 inside the plurality of nanoparticles 165 may have a substantially circular cross-section. In some embodiments, the plurality of nanoparticles 165 and the core 162 inside the plurality of nanoparticles 165 may have a substantially spherical shape. The core 162 may have a spherical shape including a center of the nanoparticle 165. For example, the nanoparticle 165 and the core 162 may have concentric cross-sections sharing a center. In some embodiments, the nanoparticle 165 and the core 162 may have a spherical shape substantially sharing a center. In some embodiments, when the plurality of nanoparticles 165 and the core 162 have substantially a spherical shape, and the core 162 includes the center of the nanoparticle 165, the shell 163 having a shape at least partially surrounding the core 162 may have a donut-shaped cross-section. In some embodiments, the shell 163 may have a spherical shape, in which the center is hollow in a spherical shape. The shell 163 may share an outer surface area with the nanoparticle 165. The outer surface area shared by the shell 163 and the nanoparticle 165 may include a boundary surface of the base dielectric layer 161. The center of the shell 163 may be hollow in a spherical shape, and accordingly, the inner surface area of the shell 163 may include a boundary surface of the core 162.

FIG. 7A is a schematic diagram of a microstructure of the ferroelectric layer 160 according to a comparative example including only the base dielectric layer 161, and FIG. 7B is a schematic diagram of a microstructure of the ferroelectric layer 160, according to an embodiment including both the base dielectric layer 161 and the nanoparticle 165.

Referring to FIGS. 6, 7A, and 7B together, the plurality of nanoparticles 165 are inserted into the ferroelectric layer 160 to facilitate the crystallization of the ferroelectric material inside the ferroelectric layer 160 may be facilitated. As illustrated in FIG. 7B, the plurality of nanoparticles 165 are inserted into the base dielectric layer 161 including a ferroelectric material, to increase a size of the surface area with respect to a particular volume of the base dielectric layer 161 and stress in the base dielectric layer 161, and accordingly implement a crystallization process. In addition, as the plurality of nanoparticles 165 are inserted into the ferroelectric layer 160, the size of the ferroelectric crystal grain may decrease due to the confinement effect. As illustrated in FIGS. 7A and 7B, the plurality of nanoparticles 165 are inserted into the base dielectric layer 161 to reduce the size of a ferroelectric crystal grain 161b compared to the size of a ferroelectric crystal grain 161a. As the size of a ferroelectric crystal grain decreases, dispersion of a crystal grain may be increased. Accordingly, embodiments of the present disclosure increase reliability of the ferroelectric transistor FTR including the ferroelectric layer 160.

According to some embodiments, as the plurality of nanoparticles 165 are inserted into the ferroelectric layer 160, the thickness of the ferroelectric layer 160 increases, and a ferroelectric material may maintain the o-phase having ferroelectric characteristics. In some embodiments, the base dielectric layer 161 may include a hafnium-based oxide having an orthorhombic crystal structure, and the hafnium-based oxide may include, for example, the o-phase having an orthorhombic crystal structure. In some embodiments, when the thickness of the ferroelectric layer 160 is increased to increase ferroelectric characteristics of the ferroelectric transistor FTR, a material in a bulk state may have a monoclinic-phase, and the ferroelectric layer 160 having the m-phase may not have ferroelectric characteristics, and thus, may have a relatively low dielectric constant. In some embodiments, when the plurality of nanoparticles 165 are inserted into the ferroelectric layer 160 according to embodiments, the o-phase having ferroelectric characteristics may be maintained even when the thickness of the ferroelectric layer 160 is increased. In some embodiments, the stress applied to the ferroelectric layer 160 increases as the plurality of nanoparticles 165 are inserted into the ferroelectric layer 160. When the stress applied to the ferroelectric layer 160 increases, the polarity of the ferroelectric material may be enforced, and a memory window may be increased. In some examples, the thickness of the ferroelectric layer 160 is increased , and the memory window of about 6.5 V or greater is secured.

In some embodiments, as the plurality of nanoparticles 165 are inserted into the ferroelectric layer 160, a ratio of materials having ferroelectric characteristics in the ferroelectric layer 160 having the same thickness may be increased, and accordingly, an increase in the thickness of the ferroelectric layer 160 may also be minimized.

In embodiments, the plurality of nanoparticles 165 may include a material other than a ferroelectric material. For example, the ferroelectric layer 160 may include the base dielectric layer 161 and the nanoparticle 165, the base dielectric layer 161 including a ferroelectric material, and the nanoparticle 165 including a plurality of non-ferroelectric materials inside the base dielectric layer 161.

In embodiments, the core 162 may include a material having a thermal expansion coefficient less than that of the ferroelectric material of the base dielectric layer 161. In embodiments, the core 162 may include a material having a thermal expansion coefficient less than that of the ferroelectric material of the base dielectric layer 161. In some embodiments, the core 162 may also include silicon oxide (SiO₂). As the core 162 includes a material having a thermal expansion coefficient less than that of the ferroelectric material of the base dielectric layer 161, tensile stress applied to the ferroelectric layer 160 may increase. As the thermal expansion coefficient of a material of the core 162 decreases, the tensile stress applied to the ferroelectric layer 160 may increase.

In some embodiments, the core 162 may also include a material having a thermal expansion coefficient greater than that of the ferroelectric material of the base dielectric layer 161. In some embodiments, the core 162 may also include a metal having a thermal expansion coefficient greater than that of the ferroelectric material of the base dielectric layer 161. As the core 162 includes a material having a thermal expansion coefficient greater than that of the ferroelectric material of the base dielectric layer 161, compressive stress applied to the ferroelectric layer 160 may increase. As the thermal expansion coefficient of a material of the core 162 increases, the compressive stress applied to the ferroelectric layer 160 may increase.

In some embodiments, the plurality of nanoparticles 165 may include a metal having a thermal expansion coefficient less than that of the ferroelectric material of the base dielectric layer 161. The core 162 may include a material having a thermal expansion coefficient greater or less than that of the ferroelectric material of the base dielectric layer 161. As the absolute value of the difference between the thermal expansion coefficient of a material of the core 162 and the thermal expansion coefficient of the ferroelectric material of the base dielectric layer 161 increases, stress applied to the ferroelectric layer 160 by the nanoparticle 165 may increase, and accordingly, crystal grain size reduction, an increase of ferroelectric characteristics, or the like described above may result in.

In embodiments, the shell 163 may include a high bandgap metal oxide. In some embodiments, the shell 163 may include a material having a bandgap energy greater than that of a material constituting the base dielectric layer 161. In some embodiments, the shell 163 may include a metal oxide having a bandgap energy greater than that of a material constituting the base dielectric layer 161. For example, the shell 163 may include aluminum oxide (Al₂O₃). As the shell 163 includes a metal oxide having a large bandgap energy, a gate leakage phenomenon may be increased. In particular, when the core 162 includes a conductor, such as a metal, a gate leakage phenomenon, that may occur due to the core 162, may be increased.

In embodiments, the thickness of the ferroelectric layer 160 may range from 0 nm to about 10 nm. The diameter of the plurality of nanoparticles 165 may range from 0 nm to about two thirds of the thickness of the ferroelectric layer 160. In some embodiments, the diameter of the plurality of nanoparticles 165 may be equal to or greater than about 1 nm to equal to or less than about 6.6 nm.

According to some embodiments, as the plurality of nanoparticles 165 are inserted into the ferroelectric layer 160, the crystal grain size may be reduced and ferroelectric characteristics of the ferroelectric layer 160 may be increased, and thus, a ferroelectric transistor FTR having increased reliability may be obtained.

In some embodiments, a transistor-one capacitor 1T-1C, in which the capacitor structure 190 is arranged on the ferroelectric transistor FTR, has been described as an example with reference to FIGS. 1 through 6. However, the inventive concept is not necessarily limited thereto, and the capacitor structure 190 may be omitted. For example, the ferroelectric transistor FTR may operate in a manner of storing data and sensing data, by using that a threshold voltage of the ferroelectric transistor FTR varies according to a polarization direction remaining in the ferroelectric layer 160. For example, a state, in which the ferroelectric transistor FTR has a relatively low first threshold voltage Vₜₕ₁, may be designated as data 1, a state, in which the ferroelectric transistor FTR has a relatively high second threshold voltage Vₜₕ₂, may be designated as data 0, and when a read voltage V_{read} higher than the first threshold voltage Vₜₕ₁ and lower than the second threshold voltage Vₜₕ₂ is applied, data may be stored/read by sensing a value of a current flowing through the ferroelectric transistor FTR.

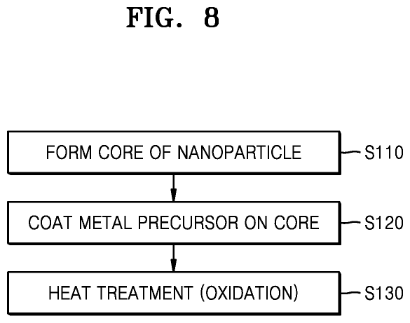

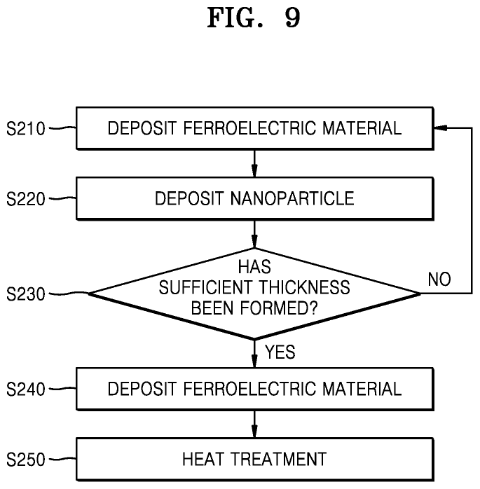

FIGS. 8 and 9 are flowcharts illustrating a manufacturing method of a semiconductor device, according to embodiments.

Referring to FIG. 8, a method for forming a plurality of nanoparticles 165 is illustrated. Firstly, the core 162 of the nanoparticle 165 may be formed (S110). Next, a metal precursor may be coated on the formed core 162 (S120). For example, an aluminum precursor may be coated on the core 162. Next, a heat treatment S130 may be applied to the core 162, on which the metal precursor has been coated. By the heat treatment, the shell 163 including a metal oxide or the like may be formed, and the nanoparticle 165 having a structure, in which the shell 163 surrounds the core 162, may be obtained. For example, when the core 162, on which the aluminum precursor has been coated, the shell 163 including aluminum oxide (Al₂O₃), may be formed. The heat treatment described above may be performed at, for example, about 600° C.

In some embodiments, the core 162 may include gold, for example, by using aluminum (Al) sample coated with gold (Au), and the shell 163 may also form the nanoparticle 165 including aluminum oxide (Al₂O₃). When a laser is irradiated to a solution containing the aluminum sample, the nanoparticle 165 of various sizes may be obtained.

In some embodiments, the nanoparticle 165 including an air gap between the core 162 and the shell 163 may be formed. The nanoparticle 165 may be obtained by using the following process. Firstly, a metal carbide may be produced by performing a one-pot reaction on the precursor containing metal chloride. The generated metal carbide may be coated with aluminum oxide (Al₂O₃) or the like, and then, the air gap between the core 162 and the shell 163 may be formed by using a process of removing the carbon C by using a calcination process. At least some of the surface of the core 162 may not contact the shell 163. By using the processes described above, the core 162 may include a metal, and the shell 163 may obtain the nanoparticle 165 having a core-shell structure including aluminum oxide (Al₂O₃), etc.

Referring to FIG. 9, a method of inserting the plurality of nanoparticles 165 obtained by the method described above into the ferroelectric layer 160 is illustrated. Firstly, a ferroelectric material is deposited (S210). Next, a plurality of nanoparticles 165 are deposited on the ferroelectric material (S220). The deposition process of the nanoparticle 165 may be performed by for example, using a spin coating process, or a process of depositing the nanoparticle 165 in a vapor state, etc. In some embodiments, at this step, the ferroelectric material before the heat treatment may not have the ferroelectric characteristics. The depositing ferroelectric material 5210 and depositing nanoparticle 5220 may be repeated until a sufficient thickness is formed (S230). After the ferroelectric material is deposited again (S240), the ferroelectric layer 160 having a structure, in which the plurality of nanoparticles 165 are inserted into the base dielectric layer 161, may be obtained (S250). By using the heat treatment process, fusion of membranes of the base dielectric layer 161 and the plurality of nanoparticles 165 may be promoted, or ferroelectric characteristics of the ferroelectric material of the base dielectric layer 161 may be enhanced.

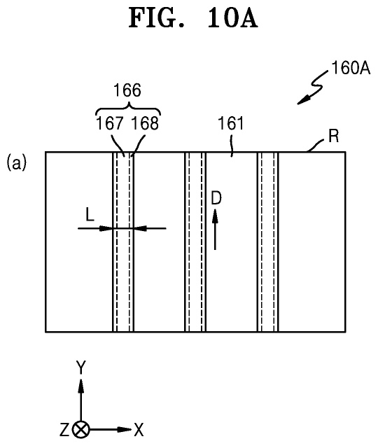

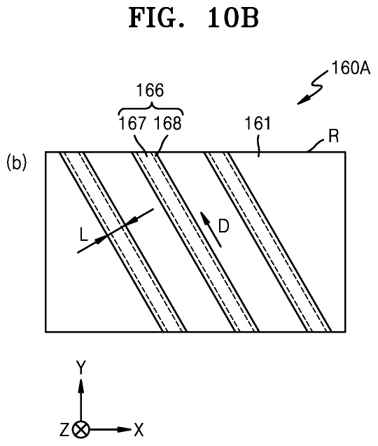

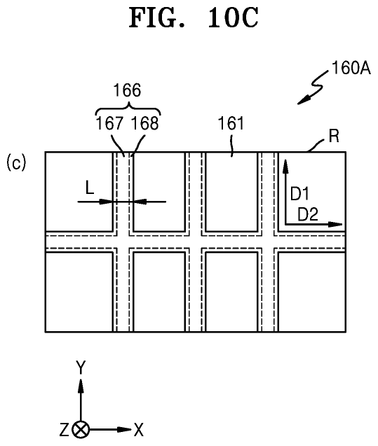

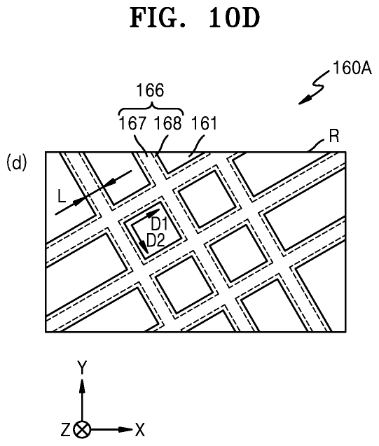

FIGS. 10A through 10D are detailed cross-sectional views of some regions of a semiconductor device according to embodiments.

Referring to FIGS. 10A through 10D, the semiconductor device 100 according to embodiments may include a limiting layer 166. A ferroelectric layer 160A may include the base dielectric layer 161 and the limiting layer 166 inserted into the base dielectric layer 161. The limiting layer 166 may have a structure inserted into the base dielectric layer 161 in the vertical direction Z. FIGS. 10A through 10D illustrate cross-sectional views, in which the semiconductor device 100 according to embodiments is cut into a plane perpendicular to the vertical direction Z.

In embodiments, as the limiting layer 166 is inserted into the ferroelectric layer 160A, crystallization of the ferroelectric material inside the ferroelectric layer 160A may be facilitated. When the limiting layer 166 is inserted into the base dielectric layer 161 including the ferroelectric material, the surface area with respect to the particular volume of the base dielectric layer 161 may increase, and stress may increase to promote the crystallization process. In embodiments, when the limiting layer 166 is inserted into the ferroelectric layer 160A, the size of the ferroelectric grain may be reduced due to the limiting effect, and the dispersion of the crystal grains may be increased.

As the limiting layer 166 is inserted into the ferroelectric layer 160A, even though the thickness of the ferroelectric layer 160 increases, the ferroelectric material may maintain the o -phase having the ferroelectric characteristics. This effect may be due to a reason that stress applied to the ferroelectric layer 160A increases as the limiting layer 166 is inserted into the ferroelectric layer 160A.

In embodiments, as the limiting layer 166 is inserted into the ferroelectric layer 160A, a ratio of materials having ferroelectric characteristics in the ferroelectric layer 160A having the same thickness may be increased, and accordingly, an increase in the thickness of the ferroelectric layer 160A may also be minimized.

The limiting layer 166 may include a material except for a ferroelectric material. In other words, the ferroelectric layer 160A may include the base dielectric layer 161 including a ferroelectric material and the limiting layer 166 including a plurality of non-ferroelectric materials inside the base dielectric layer 161.

In embodiments, as illustrated in FIGS. 10A and 10B, the limiting layer 166 may extend in one direction D. For example, the limiting layer 166 may extend in any direction D perpendicular to the vertical direction Z. In some embodiments, as illustrated in FIGS. 10C and 10D, the limiting layer 166 may extend in any two directions D1 and D2 perpendicular to the vertical direction Z. In particular, the limiting layer 166 may have a structure, in which layers extending in any two directions D1 and D2 perpendicular to the vertical direction Z intersect each other.

The limiting layer 166 may include multiple layers. In particular, the limiting layer 166 may include a center layer 167 and the periphery layer 168 at least partially surrounding the center layer 167. The center layer 167 may include a central portion of the limiting layer 166, and the periphery layer 168 may have a structure at least partially surrounding the center layer 167 in all directions. The center layer 167 and the periphery layer 168 may extend in the same direction as the limiting layer 166. In particular, the periphery layer 168 may at least partially surround the center layer 167, and extend in the same direction as a direction, in which the limiting layer 166 extends. The limiting layer 166 may have a thickness L of about 0.05 nm to about 5 nm in a direction perpendicular to a direction, in which the limiting layer 166 extends.

In some embodiments, the center layer 167 may include a material having a thermal expansion coefficient greater or less than that of the ferroelectric material of the base dielectric layer 161. As the absolute value of the difference between the thermal expansion coefficient of a material of the center layer 167 and the thermal expansion coefficient of the ferroelectric material of the base dielectric layer 161 increases, stress applied to the base dielectric layer 161 by the limiting layer 166 may increase, and accordingly, crystal grain size is reduced, and ferroelectric characteristics or the like are increased.

The limiting layer 166 may include a high bandgap material. In particular, the limiting layer 166 may include a high bandgap metal oxide. The periphery layer 168 may include a high bandgap metal oxide. In some embodiments, the periphery layer 168 may include a material having a bandgap energy greater than that of a material constituting the base dielectric layer 161. In some embodiments, the periphery layer 168 may include a metal oxide having a bandgap energy greater than that of a material constituting the base dielectric layer 161. For example, the periphery layer 168 may include aluminum oxide (Al₂O₃). As the periphery layer 168 includes a metal oxide having a large bandgap energy, a gate leakage phenomenon may be increased. In particular, when the center layer 167 includes a conductor, such as a metal, a gate leakage phenomenon, that may occur due to the center layer 167, may be increased.

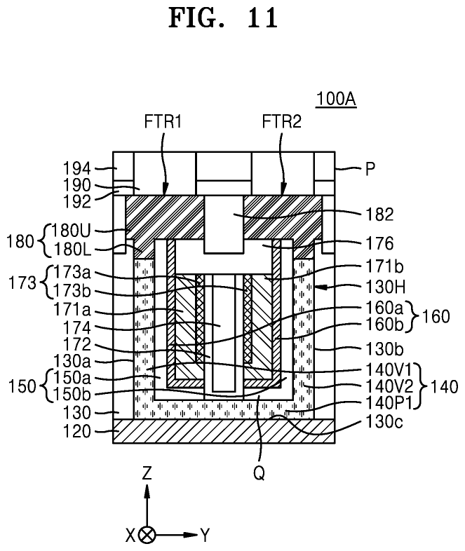

FIG. 11 is a cross-section view of a semiconductor device 100A according to embodiments. The semiconductor device 100A illustrated in FIG. 11 may refer to the semiconductor device 100 illustrated in FIG. 4.

Referring to FIG. 11, a word line 171 may have an L-shaped vertical cross-section, and a second word line 171b may have a mirror symmetry shape with respect to a first word line 171a. The first word line 171a may include a vertical extension portion arranged on the first sidewall 130a of the opening 130H of the mold insulating layer 130, and a horizontal extension portion extending in the horizontal direction from a lower end of the vertical extension portion, and the second word line 171b may include a vertical extension portion and a horizontal extension portion, the vertical extension portion arranged on the second sidewall 130b of the opening 130H of the mold insulating layer 130 and the horizontal extension portion extending in the horizontal direction from the lower end of the vertical extension portion.

A spacer 173 may be arranged between the word line 171 and the insulating liner 172, and the spacer 173 may be arranged on the horizontal extension portion of the word line 171. In other words, a first spacer 173a may be arranged between the first word line 171a and the insulating liner 172, and a second spacer 173b may be arranged between the second word line 171b and the insulating liner 172. The first spacer 173a may be arranged on the horizontal extension portion of the first word line 171a, and the second spacer 173b may be arranged on the horizontal extension portion of one or more of the second word lines 171b.

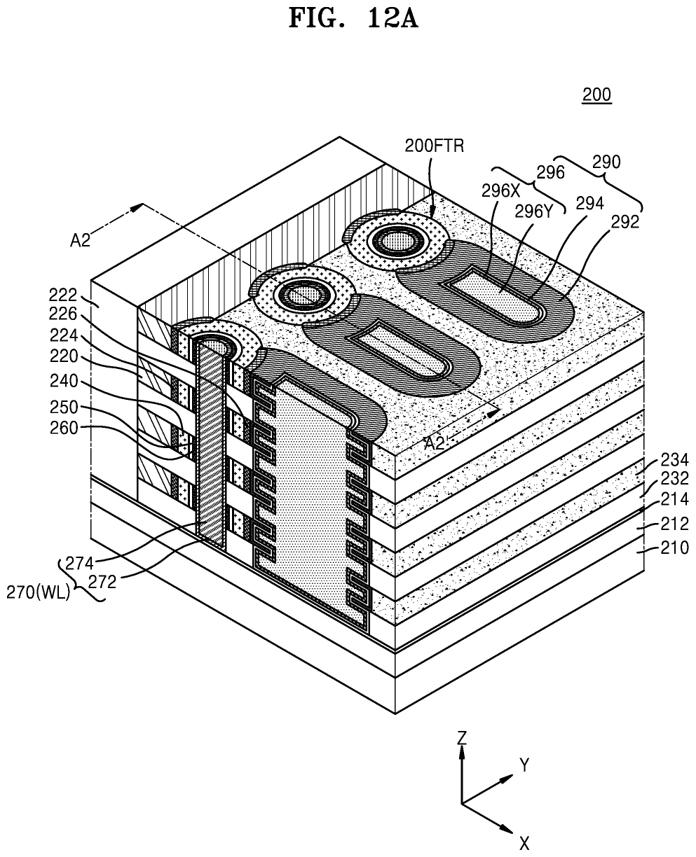

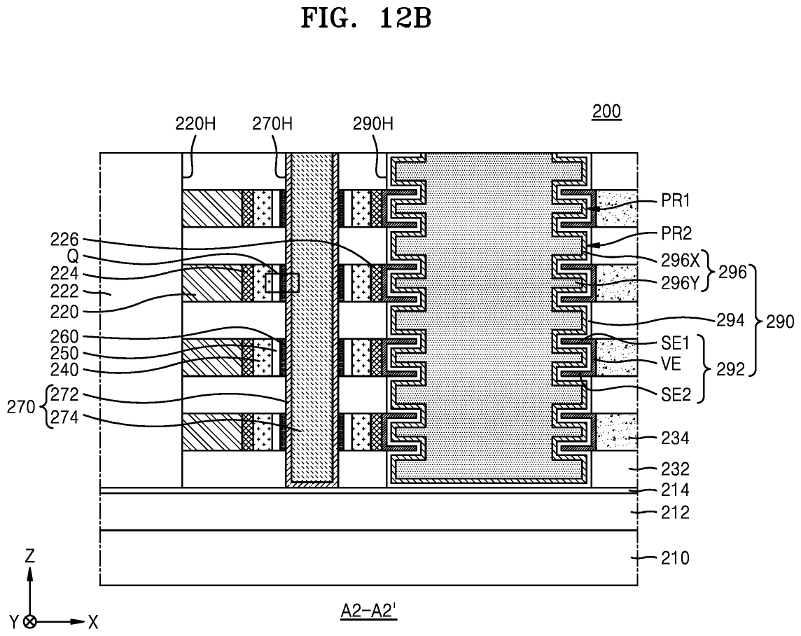

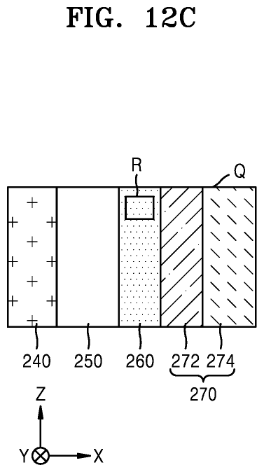

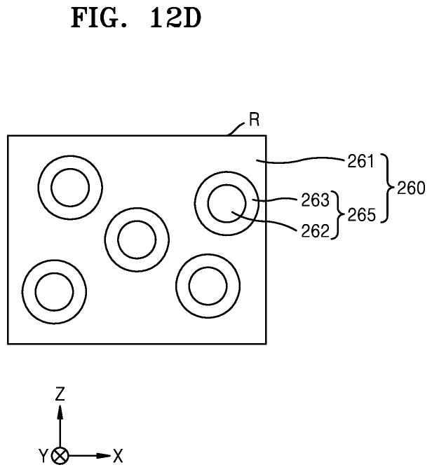

FIGS. 12A through 12D are diagrams of a semiconductor device 200 including a ferroelectric transistor 200FTR according to the technical idea of the inventive concept. FIG. 12A is a perspective view of the semiconductor device 200 according to embodiments. FIG. 12B is a cross-sectional view taken along line A2-A2′ in FIG. 12A. FIG. 12C is a detailed cross-sectional view of region Q in FIG. 12B. FIG. 12D is a detailed cross-sectional view of region R in FIG. 12C.

Referring to FIGS. 12A and 12B, the semiconductor device 200 may include a plurality of bit lines 220, a channel layer 240, a gate insulating layer 250, a ferroelectric layer 260, a plurality of word lines 270, and a capacitor structure 290, which are arranged on a substrate 210. The semiconductor device 200 may include the ferroelectric transistor 200FTR. The ferroelectric transistor 200FTR may include the channel layer 240, the gate insulating layer 250, the ferroelectric layer 260, and the word line 270.

A lower structure 212 may be arranged on the substrate 210. The lower structure 212 may include a periphery circuit, a wiring layer connected to the periphery circuit, and an insulating layer covering the periphery circuit and the wiring layer. An etch stop layer 214 may be arranged on the lower structure 212. The etch stop layer 214 may include silicon nitride or silicon oxide.

A plurality of mold insulating layers 232 and a plurality of sacrificial insulating layers 234 may be alternately arranged on the etch stop layer 214. The plurality of mold insulating layers 232 and the plurality of sacrificial insulating layers 234 may include at least one of silicon oxide, silicon nitride, and silicon oxynitride. In embodiments, the plurality of mold insulating layers 232 and the plurality of sacrificial insulating layers 234 may include a material having an etching selectivity with respect to each other. For example, the mold insulating layer 232 may include silicon oxide, and the sacrificial insulating layer 234 may include silicon nitride.

The plurality of word lines 270 may be apart from each other on the substrate 210 in the second horizontal direction Y, and may extend in the vertical direction Z. The plurality of word lines 270 may be arranged in a word line opening 270H penetrating the plurality of mold insulating layers 232.

The plurality of word lines 270 may include a conductive barrier layer 272 arranged on an inner sidewall of the word line opening 270H, and a buried conductive layer 274 filling the inside of the word line opening 270H on the conductive barrier layer 272. For example, the conductive barrier layer 272 and the buried conductive layer 274 may include at least one of a doped semiconductor material (doped silicon, doped germanium, or the like), a conductive metal nitride (titanium nitride, tantalum nitride, or the like), a metal-semiconductor compound (tungsten silicide, cobalt silicide, titanium silicide, or the like). Although the plurality of word lines 270 in FIGS. 12A and 12B are exemplarily illustrated as having a circular horizontal cross-section, the inventive concept is not limited thereto.

A plurality of channel layers 240 may be arranged apart from each other in the vertical direction Z on sidewalls of one or more of the plurality of word lines 270. The plurality of channel layers 240 may have a ring shape at least partially surrounding the sidewalls of the word line 270. The plurality of channel layers 240 and the plurality of mold insulating layers 232 may be alternately arranged on the sidewalls of the word line 270, and may at least partially surround the sidewall portions of the word line 270, where the mold insulating layer 232 is not covered by the plurality of channel layers 240.

The plurality of channel layers 240 may include, for example, an undoped semiconductor material or a doped semiconductor material. In some embodiments, the plurality of channel layers 240 may include polysilicon. In some embodiments, the plurality of channel layers 240 may include an amorphous metal oxide, a polycrystalline metal oxide, a combination of an amorphous metal oxide and a polycrystalline metal oxide, or the like, and may include at least one of, for example, In—Ga base oxide (IGO), In—Ga—Zn base oxide (IZO), or IN—Ga—Zn base oxide (INZO). In some embodiments, the plurality of channel layers 240 may include a two-dimensional (2D) material semiconductor, and the 2D material semiconductor may include, for example, MoS₂, WSe₂, graphene, carbon nanotubes, or a combination thereof.

The gate insulating layer 250 may be between the word line 270 and the channel layer 240. In some embodiments, as illustrated in FIG. 12B, the gate insulating layer 250 may cover only the sidewall portions of the word line 270 surrounded by the channel layer 240. In this case, the gate insulating layer 250 may not be on the sidewall portions of the word line 270 surrounded by the mold insulating layer 232, and the mold insulating layer 232 may directly contact the sidewalls of the word line 270.

In some embodiments, unlike as illustrated in FIG. 12B, the gate insulating layer 250 may extend in the vertical direction Z over the total height of the word line 270 to cover the total sidewalls of the word line 270. In this case, the gate insulating layer 250 may be between the mold insulating layer 232 and the word line 270, but the mold insulating layer 232 may not directly contact the word line 270.

The ferroelectric layer 260 may be between the gate insulating layer 250 and the word line 270. In some embodiments, like the gate insulating layer 250 illustrated in FIG. 12B, the ferroelectric layer 260 may cover only the sidewall portion of the word line 270 surrounded by the channel layer 240. In this case, the ferroelectric layer 260 may not be on the sidewall portions of the word line 270 surrounded by the mold insulating layer 232, and the mold insulating layer 232 may directly contact the sidewalls of the word line 270.

In some embodiments, the ferroelectric layer 260 may extend in the vertical direction Z over the total height of the word line 270 to cover the total sidewalls of the word line 270. In this case, the ferroelectric layer 260 may be between the mold insulating layer 232 and the word line 270, but the mold insulating layer 232 may not directly contact the word line 270.

A portion of the word line 270, the channel layer 240 at least partially surrounding the portion of the word line 270, the ferroelectric layer 260 sequentially arranged between the word line 270 and the channel layer 240, and the gate insulating layer 250 may constitute the ferroelectric transistor 200FTR. Accordingly, a word line 270 and the plurality of channel layers 240 at least partially surrounding the word line 270 may constitute a plurality of ferroelectric transistors arranged in the vertical direction Z.

The plurality of bit lines 220 may extend in the second horizontal direction Y to be adjacent to respective ends of the plurality of channel layers 240, and may be arranged apart from each other in the vertical direction Z. The mold insulating layer 232 may be arranged between two bit lines 220 adjacent to each other in the vertical direction Z. The plurality of bit lines 220 may include a doped semiconductor material, a conductive metal nitride, a metal, and a metal-semiconductor compound.

A bit line insulating layer 222 may be arranged in the bit line opening 220H. In some embodiments, the bit line insulating layer 222 penetrates the plurality of mold insulating layers 232 and extends in the second horizontal direction Y. The sidewalls of the bit line insulating layer 222 may contact the sidewalls of the plurality of bit lines 220 and the sidewalls of the plurality of mold insulating layers 232.

A first impurity region 224 may be arranged between the plurality of bit lines 220 and the plurality of channel layers 240 connected thereto. In embodiments, the first impurity region 224 may include a semiconductor material doped with a high concentration of impurities. For example, the first impurity region 224 may include an n+ region.

A second impurity region 226 may be arranged between the plurality of channel layers 240 and the capacitor structure 290 connected thereto. In embodiments, the second impurity region 226 may include a semiconductor material doped with a high concentration of impurities. For example, the second impurity region 226 may include an n+ region.

A plurality of capacitor structures 290 may be arranged at the other ends of the plurality of channel layers 240. The plurality of capacitor structures 290 may be arranged inside a capacitor opening 290H, which penetrates the plurality of mold insulating layers 232 and the plurality of sacrificial insulating layers 234, and extends in the vertical direction Z.

The plurality of capacitor structures 290 may extend in the vertical direction Z, and may be arranged apart from each other in the second horizontal direction Y. A capacitor structure 290 may be connected to the plurality of channel layers 240 overlapping each other in the vertical direction Z. In addition, the plurality of bit lines 220 may be arranged at one ends of the plurality of channel layers 240 in the first horizontal direction X, and the capacitor structure 290 may be arranged at the other ends of the plurality of channel layers 240 in the first horizontal direction X.

The capacitor structure 290 may include a plurality of lower electrode layers 292, a capacitor dielectric layer 294, and an upper electrode layer 296. The plurality of lower electrode layers 292 may be arranged at the other ends of the plurality of channel layers 240, and an outer surface of one or more of the plurality of lower electrode layers 292 may be surrounded by a plurality of sacrificial insulating layers 234. The upper electrode layer 296 may be surrounded by the plurality of lower electrode layers 292 and may extend in the vertical direction Z. The capacitor dielectric layer 294 may be between the plurality of lower electrode layers 292 and the upper electrode layer 296.

In embodiments, one or more of the plurality of lower electrode layers 292 may have a ring-shaped horizontal cross-section. For example, as illustrated in FIG. 12A, the plurality of lower electrode layers 292 may have an elliptical horizontal cross-section, in which a length in the first horizontal direction X is greater than a length in the second horizontal direction Y, but are not limited thereto. In some embodiments, the plurality of lower electrode layers 292 may have a length in the first horizontal direction X equal to a length in the second horizontal direction Y, or may also have a length in the first horizontal direction X less than a length in the second horizontal direction Y.

In embodiments, one or more of the plurality of lower electrode layers 292 may have an about 90 degrees-rotated U-shaped vertical cross-section. As illustrated in FIG. 12B, one or more of the plurality of lower electrode layers 292 may include a connection VE extending in the vertical direction Z, a first segment SE1 extending in the horizontal direction from an upper end of the connection VE, and a second segment SE2 extending in the horizontal direction. For example, a horizontal cross-section of one or more of the connection VE, the first segment SE1, and the second segment SE2 may have a ring shape. The connection VE may be arranged on an inner sidewall of the capacitor opening 290H, and an outer surface of the connection VE may be surrounded by the plurality of sacrificial insulating layers 234. The first segment SE1 and the second segment SE2 may protrude from the connection VE toward the inside of the capacitor opening 290H, and may extend in the horizontal direction.

In embodiments, the upper electrode layer 296 may include a plurality of first protrusions PR1 protruding outward toward a plurality of lower electrode layers 129, and a plurality of second protrusions PR2 protruding outward toward the plurality of mold insulating layers 232. For example, one or more of the plurality of first protrusions PR1 and the plurality of second protrusions PR2 may have a ring-shaped horizontal cross-section. The plurality of first protrusions PR1 and the plurality of second protrusions PR2 may be alternately arranged in the vertical direction Z, and may overlap each other in the vertical direction Z. Both outer surfaces of the plurality of first protrusions PR1 and outer surfaces of the plurality of second protrusions PR2 may be conformally covered by the capacitor dielectric layer 294.

In embodiments, the upper electrode layer 296 may cover an upper surface and a bottom surface of the first segment SE1 of a lower electrode layer 292, an upper surface and a bottom surface of the second segment SE2, and an inner sidewall of the connection VE. One or more of the plurality of first protrusions PR1 may fill a space limited by the inner sidewall of the connection VE of a lower electrode layer 292, the bottom surface of the first segment SE1, and the upper surface of the second segment SE2, and may fill a space limited by the inner sidewall of the capacitor opening 290H, the bottom surface of the second segment SE2 of one lower electrode layer 292, and the upper surface of the first segment SE1 of the other lower electrode layer 292 at a level higher than the plurality of first protrusions PR1.

In embodiments, the lower electrode layer 292 may include a doped semiconductor material, a conductive metal nitride, such as a titanium nitride, a tantalum nitride, a niobium nitride, and a tungsten nitride, a conductive metal oxide, such as ruthenium, iridium, a titanium metal, a tantalum metal, an iridium oxide, and a niobium oxide.

In embodiments, the upper electrode layer 296 may include a first upper electrode layer 296X and a second upper electrode layer 296Y. For example, the first upper electrode layer 296X may be arranged on the capacitor dielectric layer 294, and the second upper electrode layer 296Y may fill the inner space of the capacitor opening 290H on a first upper electrode layer 294X. One or more of the first upper electrode layer 296X and the second upper electrode layer 296Y may include a doped semiconductor material, a conductive metal nitride, such as a titanium nitride, a tantalum nitride, a niobium nitride, and a tungsten nitride, a conductive metal oxide, such as ruthenium, iridium, a titanium metal, a tantalum metal, an iridium oxide, and a niobium oxide.

In embodiments, the capacitor dielectric layer 294 may include at least one selected from a high-k dielectric material and a ferroelectric material having a dielectric constant higher than that of silicon oxide. In some embodiments, the capacitor dielectric layer 294 may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), and lead scandium tantalum oxide (PbScTaO).

FIG. 12C is a detailed cross-sectional view of region Q in FIG. 12B. Particularly, a cross-sectional view of a portion of the ferroelectric transistor 200FTR included in the semiconductor device 200 according to embodiments. The region Q illustrated in FIG. 12C may include a portion of the ferroelectric transistor 200FTR including the ferroelectric layer 260.

Referring to FIG. 12C, the ferroelectric transistor 200FTR may include the channel layer 240, the gate insulating layer 250, the ferroelectric layer 260, and the word line 270. The ferroelectric transistor 200FTR may include the channel layer 240, the gate insulating layer 250, the ferroelectric layer 260, and the word line 270, which are sequentially stacked.

FIG. 12C is a detailed cross-sectional view of region R in FIG. 12C. Particularly, a cross-sectional view of a portion of the ferroelectric transistor 200FTR included in the semiconductor device 200 according to embodiments. The region R illustrated in FIG. 12D may include a portion of the ferroelectric layer 260 of the ferroelectric transistor 200FTR.

The ferroelectric layer 260 may include a base dielectric layer 261 and a plurality of nanoparticles 265, the plurality of nanoparticles 265 dispersed and arranged in the base dielectric layer 261. The base dielectric layer 261 may include a ferroelectric material. The plurality of nanoparticles 265 may have a core 262-shell 263 structure. The core 262 may include a portion formed in the nanoparticles 265 and having a particular volume, and the shell 263 may include a portion corresponding to the nanoparticles 265 except for the core 262, and may have a shape at least partially surrounding the core 262.

As the plurality of nanoparticles 265 are inserted into the ferroelectric layer 260, crystallization of the ferroelectric material inside the ferroelectric layer 260 may be facilitated. In addition, as the plurality of nanoparticles 265 are inserted into the ferroelectric layer 260, the size of the ferroelectric crystal grain may decrease due to the confinement effect.

The plurality of nanoparticles 265 may include a metal having a thermal expansion coefficient less than that of the ferroelectric material of the base dielectric layer 261. The core 262 may include a material having a thermal expansion coefficient greater or less than that of the ferroelectric material of the base dielectric layer 261. The plurality of nanoparticles 265 may include a high bandgap material. In particular, the nanoparticle 265 may include a high bandgap metal oxide. The shell 263 may include a high bandgap metal oxide. In some embodiments, the shell 263 may include a material having a bandgap energy greater than that of a material constituting the base dielectric layer 261.

As the absolute value of the difference between the thermal expansion coefficient of a material of the core 262 and the thermal expansion coefficient of the ferroelectric material of the base dielectric layer 261 increases, stress applied to the ferroelectric layer 260 by the nanoparticle 265 may increase, and accordingly, crystal grain size reduction, an increase of ferroelectric characteristics, or the like described above may result in. As the shell 263 includes a metal oxide having a large bandgap energy, a gate leakage phenomenon may be increased.

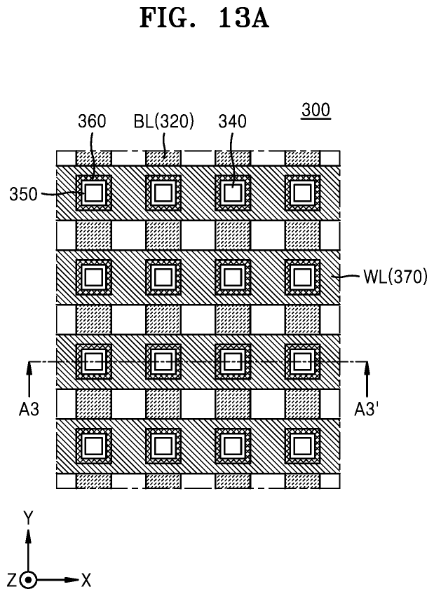

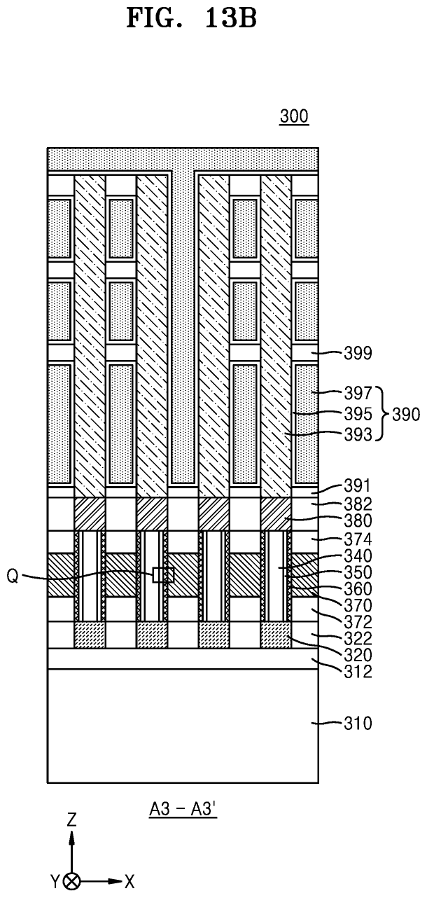

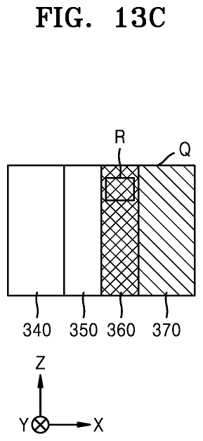

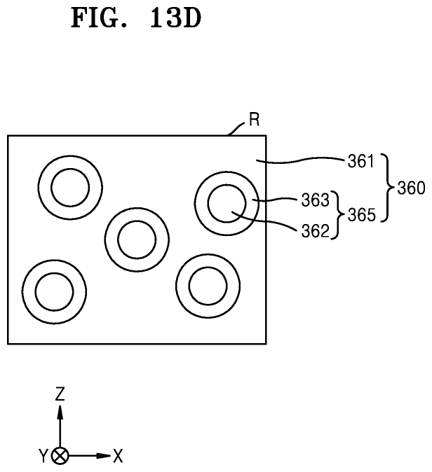

FIGS. 13A through 13D are diagrams of a semiconductor device 300 including a ferroelectric transistor 300FTR, according to the technical idea of the inventive concept. FIG. 13A is a layout diagram of a semiconductor device according to embodiments. FIG. 13B is a cross-sectional view taken along line A3-A3′ in FIG. 13A. FIG. 13C is a detailed cross-sectional view of region Q in FIG. 13B. FIG. 13D is a detailed cross-sectional view of region R in FIG. 13C.

Referring to FIGS. 13A and 13B, the semiconductor device 300 may include a plurality of bit lines 320, a channel layer 340, a gate insulating layer 350, a ferroelectric layer 360, a plurality of word lines 370, and a capacitor structure 390, which are arranged on a substrate 310. The semiconductor device 300 may be a memory device including a vertical channel transistor (VCT), and the VCT may be referred to as a structure, in which a channel length of the channel layer 340 extends from the substrate 310 in the vertical direction Z. The semiconductor device 300 may include the ferroelectric transistor 300FTR. The ferroelectric transistor 300FTR may include the channel layer 340, the gate insulating layer 350, the ferroelectric layer 360, and the word line 370.

A lower insulating layer 312 may be arranged on the substrate 310, and the plurality of bit lines 320 may be apart from each other in the first direction X and extend in the second direction Y on the lower insulating layer 312. A plurality of first insulating patterns 322 may be arranged to fill spaces between the plurality of bit lines 320 on the lower insulating layer 312. The plurality of bit lines 320 illustrated in FIG. 13B may correspond to the plurality of bit lines BL illustrated in FIG. 13A.

The channel layer 340 may be arranged in an island shape and apart from each other in the first horizontal direction X and the second horizontal direction Y on the plurality of bit lines 320. The channel layer 340 may have a first width in the first horizontal direction X and a first height in the vertical direction Z, and the first height may be greater than the first width. For example, the first height may be about 2 to about 10 times the first width, but is not limited thereto. A bottom portion of the channel layer 340 may function as a first source/drain region, an upper portion of the channel layer 340 may function as a second source/drain region, and a portion of the channel layer 340 between the first and second source/drain regions may function as a channel region.

The word line 370 may at least partially surround the sidewalls of the channel layer 340, and extend in the first horizontal direction X. In a plan view, the word line 370 may include a gate-all-around-type gate electrode at least partially surrounding the entire sidewalls (for example, all four sidewalls) of the channel layer 340. The plurality of word lines 370 illustrated in FIG. 13B may correspond to the plurality of word lines WL illustrated in FIG. 13A.

In some embodiments, the word line 370 may include a dual gate-type gate electrode, and for example, may include a first word line facing the first sidewall of the channel layer 340 and a second word line facing the second sidewall opposite to the first sidewall of the channel layer 340. In addition, in some embodiments, the word line 370 may also include a single gate-type word line, which covers only the first sidewall of the channel layer 340 and extends in the first horizontal direction X.

The gate insulating layer 350 and the ferroelectric layer 360 may be sequentially arranged between the channel layer 340 and the word line 370. The gate insulating layer 350 may at least partially surround sidewalls of the channel layer 340, and may be between the channel layer 340 and the ferroelectric layer 360. The ferroelectric layer 360 may at least partially surround sidewalls of the gate insulating layer 350, and may be between the gate insulating layer 350 and the word line 370.

A first buried insulating layer 372 at least partially surrounding a lower sidewall of the channel layer 340 may be arranged on the plurality of first insulating patterns 322, and a second buried insulating layer 374 at least partially surrounding a lower sidewall of the channel layer 340 and covering the word line 370 may be arranged on the first buried insulating layer 372.

A capacitor contact 380 may be arranged on the channel layer 340. The capacitor contacts 380 may be arranged to vertically overlap the channel layers 340, and may be arranged apart from each other in a matrix form in the first horizontal direction X and the second horizontal direction Y. The capacitor contact 380 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but is not limited thereto. The upper insulating layer 382 may at least partially surround sidewalls of the capacitor contact 380 on the second buried insulating layer 374.

An etch stop layer 391 may be arranged on the upper insulating layer 382, and the capacitor structure 390 may be arranged on the etch stop layer 391. A support member 399 may be arranged on sidewalls of a lower electrode 393.

FIG. 13C is a detailed cross-sectional view of region Q in FIG. 13B. Particularly, a cross-sectional view of a portion of the ferroelectric transistor 300FTR included in the semiconductor device 300 according to embodiments. The region Q illustrated in FIG. 13C may include a portion of the ferroelectric transistor 300FTR including the ferroelectric layer 360.

Referring to FIG. 13C, the ferroelectric transistor 300FTR may include the channel layer 340, the gate insulating layer 350, the ferroelectric layer 360, and the word line 370. The ferroelectric transistor 300FTR may include the channel layer 340, the gate insulating layer 350, the ferroelectric layer 360, and the word line 370, which are sequentially stacked.

FIG. 13D is a detailed cross-sectional view of region R in FIG. 13C. Particularly, a cross-sectional view of a portion of the ferroelectric transistor 300FTR included in the semiconductor device 300 according to embodiments is illustrated. The region R illustrated in FIG. 13D may include a portion of the ferroelectric layer 360 of the ferroelectric transistor 300FTR.

The ferroelectric layer 360 may include a base dielectric layer 361 and a plurality of nanoparticles 365 dispersed and arranged, the plurality of nanoparticles 365 in the base dielectric layer 361. The base dielectric layer 361 may include a ferroelectric material. The plurality of nanoparticles 365 may have a core 362-shell 363 structure. The core 362 may include a portion formed in the nanoparticle 365 and having a particular volume, and the shell 363 may include a portion corresponding to the nanoparticle 365 except for the core 362, and may have a shape at least partially surrounding the core 362.

As the plurality of nanoparticles 365 are inserted into the ferroelectric layer 360, crystallization of the ferroelectric material inside the ferroelectric layer 360 may be facilitated. In addition, as the plurality of nanoparticles 365 are inserted into the ferroelectric layer 360, the size of the ferroelectric crystal grain may decrease due to the confinement effect.

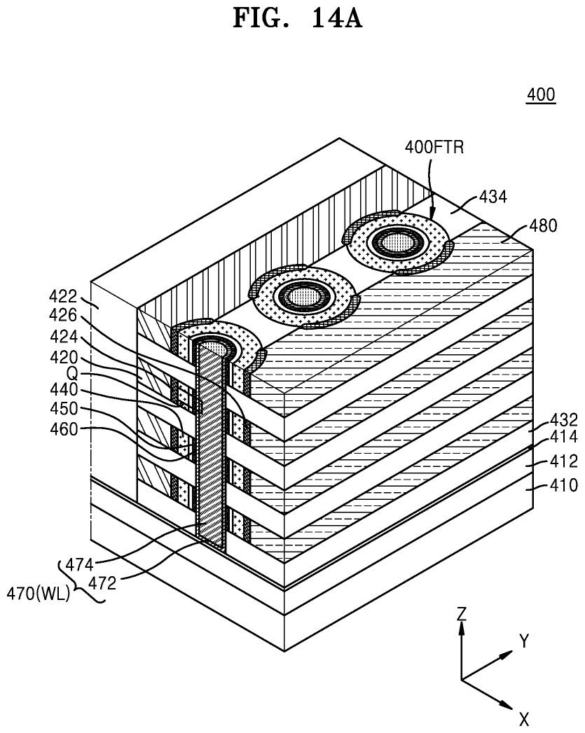

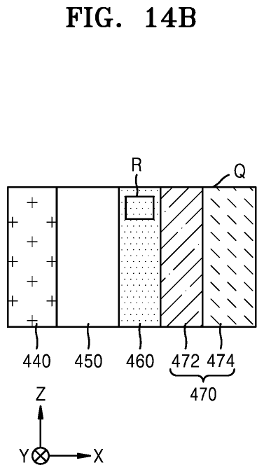

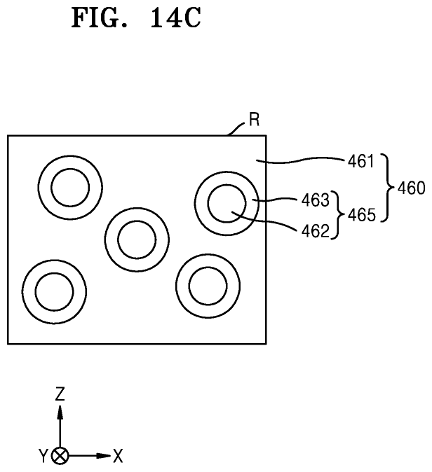

FIG. 14A is a perspective view of a semiconductor device 400 according to embodiments. FIG. 14B is a detailed cross-sectional view of region Q in FIG. 14A. FIG. 14C is a detailed cross-sectional view of region Q in FIG. 14B.

Referring to FIG. 14A, the semiconductor device 400 may include a plurality of bit lines 420, a channel layer 440, a gate insulating layer 450, a ferroelectric layer 460, and a plurality of word lines 470, which are arranged on a substrate 410. The semiconductor device 400 may include a ferroelectric transistor 400FTR. The ferroelectric transistor 400FTR may include the channel layer 440, the gate insulating layer 450, the ferroelectric layer 460, and the word line 470.

A lower structure 412 may be arranged on the substrate 410. The lower structure 412 may include a periphery circuit, a wiring layer connected to the periphery circuit, and an insulating layer covering the periphery circuit and the wiring layer. An etch stop layer 414 may be arranged on the lower structure 412. The etch stop layer 414 may include silicon nitride or silicon oxide.

A plurality of mold insulating layers 432 and a plurality of sacrificial insulating layers 434 may be alternately arranged on the etch stop layer 414. The plurality of mold insulating layers 432 and the plurality of sacrificial insulating layers 434 may include at least one of silicon oxide, silicon nitride, and silicon oxynitride.

A plurality of word lines 470 may be apart from each other on the substrate 410 in the second horizontal direction Y, and may extend in the vertical direction Z. The plurality of word lines 470 may be arranged in word line openings penetrating the plurality of mold insulating layers 432.

The plurality of word lines 470 may include a conductive barrier layer 472 arranged on an inner sidewall of the word line opening 470H, and a buried conductive layer 474 filling the inside of the word line opening 470H on the conductive barrier layer 472.

A plurality of channel layers 440 may be arranged apart from each other in the vertical direction Z on sidewalls of one or more of the plurality of word lines 470. The plurality of channel layers 440 may have a ring shape at least partially surrounding the sidewalls of the word line 470. The plurality of channel layers 440 and the plurality of mold insulating layers 432 may be alternately arranged on the sidewalls of the word line 470, and may at least partially surround the sidewall portions of the word line 470, where a mold insulating layer 432 is not covered by the plurality of channel layers 440.

The gate insulating layer 450 may be between the word line 470 and the channel layer 440. The ferroelectric layer 460 may be between the gate insulating layer 450 and the word line 470.

A portion of the word line 470, the channel layer 440 at least partially surrounding the portion of the word line 470, the ferroelectric layer 460 sequentially arranged between the word line 470 and the channel layer 440, and the gate insulating layer 450 may constitute the ferroelectric transistor 400FTR. Accordingly, the word line 470 and the plurality of channel layers 440 at least partially surrounding the word line 470 may constitute a plurality of ferroelectric transistors arranged in the vertical direction Z.

The plurality of bit lines 420 may extend in the second horizontal direction Y to be adjacent to respective ends of the plurality of channel layers 440, and may be arranged apart from each other in the vertical direction Z. The mold insulating layer 432 may be arranged between two bit lines 420 adjacent to each other in the vertical direction Z. The plurality of bit lines 420 may include any one of a doped semiconductor material, a conductive metal nitride, a metal, and a metal-semiconductor compound.

A bit line insulating layer 422 may be arranged in the bit line opening, which penetrates the plurality of mold insulating layers 432 and extends in the second horizontal direction Y. The sidewalls of the bit line insulating layer 422 may contact the sidewalls of the plurality of bit lines 420 and the sidewalls of the plurality of mold insulating layers 432.

A first impurity region 424 may be arranged between the plurality of bit lines 420 and the plurality of channel layers 440 connected thereto. In embodiments, the first impurity region 424 may include a semiconductor material doped with a high concentration of impurities. For example, the first impurity region 424 may include an n+ region.

A second impurity region 426 may be arranged between the plurality of channel layers 440 and a source line 480 connected thereto. In embodiments, the second impurity region 426 may include a semiconductor material doped with a high concentration of impurities. For example, the second impurity region 426 may include an n+ region.

A plurality of source lines 480 may extend in the second horizontal direction Y to be adjacent to respective ends of the plurality of channel layers 440, and may be arranged apart from each other in the vertical direction Z. The mold insulating layer 432 may be arranged between two source lines 480 adjacent to each other in the vertical direction Z. The plurality of source lines 480 may include Ti, TiN, Ta, TaN, W, WN, TiSiN, WSiN, polysilicon, or a combination thereof.

According to some embodiments, the semiconductor device 400 partially illustrated in FIG. 14A may not include a capacitor. In this case, the ferroelectric transistor 400FTR may operate in a manner of storing data and sensing data, by using that a threshold voltage of the ferroelectric transistor 400FTR varies according to a polarization direction remaining in the ferroelectric layer 460.

Referring to FIG. 14B, the ferroelectric transistor 400FTR may include the channel layer 440, the gate insulating layer 450, the ferroelectric layer 460, and the word line 470. The ferroelectric transistor 400FTR may include the channel layer 440, the gate insulating layer 450, the ferroelectric layer 460, and the word line 470, which are sequentially stacked.

In FIG. 14C, a cross-sectional view of a portion of the ferroelectric transistor 400FTR included in the semiconductor device 400 according to embodiments is illustrated. The region R illustrated in FIG. 14C may include a portion of the ferroelectric layer 460 of the ferroelectric transistor 400FTR.

The ferroelectric layer 460 may include a base dielectric layer 461 and a plurality of nanoparticles 465, the plurality of nanoparticles 465 dispersed and arranged in the base dielectric layer 461. The base dielectric layer 461 may include a ferroelectric material. The plurality of nanoparticles 465 may have a core 462-shell 463 structure. The core 462 may include a portion formed in the nanoparticle 465 and having a particular volume, and the shell 463 may include a portion corresponding to the nanoparticle 465 except for the core 462, and may have a shape at least partially surrounding the core 462.

In some embodiments, the plurality of nanoparticles 465 are inserted into the ferroelectric layer 460 to facilitate the crystallization of the ferroelectric material inside the ferroelectric layer 460. In some embodiments, as the plurality of nanoparticles 465 are inserted into the ferroelectric layer 460, the size of the ferroelectric crystal grain may decrease due to the confinement effect.

While the inventive concept has been particularly shown and described with reference to embodiments thereof, it will be understood that various changes in form and details may be made therein without departing from the spirit and scope of the following claims.

What is claimed is:

1. A semiconductor device comprising:
a plurality of bit lines arranged on a substrate and extending in a first horizontal direction;
a plurality of channel layers respectively arranged on the plurality of bit lines;
a plurality of word lines respectively arranged on the plurality of channel layers, and extending in a second horizontal direction; and
a plurality of ferroelectric layers arranged between the plurality of channel layers and the plurality of word lines,
wherein the plurality of ferroelectric layers comprise a base dielectric layer and a nanoparticle, the nanoparticle dispersed and arranged in the base dielectric layer, respectively,
wherein the nanoparticle has a core-shell structure including a core and a shell,
wherein the core includes a portion formed inside the nanoparticle and having a particular volume, and
wherein the shell includes a portion corresponding to the nanoparticle except for the core and at least partially surrounds the core.

2. The semiconductor device of claim 1, wherein the core and the nanoparticle each has a substantially spherical shape.

3. The semiconductor device of claim 1, wherein the shell comprises a metal oxide having a greater bandgap energy than a material constituting the base dielectric layer.

4. The semiconductor device of claim 1, wherein the shell comprises aluminum oxide.

5. The semiconductor device of claim 1, wherein the core comprises tungsten (W) or silicon oxide (SiO₂).

6. The semiconductor device of claim 1, further comprising a gate insulating layer arranged between the ferroelectric layer and the channel layer.

7. The semiconductor device of claim 1, further comprising a mold insulating layer including a plurality of openings respectively arranged on the plurality of bit lines, and one or more of the plurality of openings extending in the second horizontal direction,
wherein a channel layer of the plurality of channel layers comprises:
a first vertical extension portion arranged on a first sidewall of an opening of the plurality of the openings;
a second vertical extension portion arranged on a second sidewall of the opening; and
a horizontal extension portion arranged on a bottom portion of the opening and arranged on a respective bit line of the plurality of bit lines.

8. The semiconductor device of claim 1, further comprising a mold insulating layer including a plurality of openings respectively arranged on the plurality of bit lines, and one or more of the plurality of openings extending in the second horizontal direction,
wherein a word line of the plurality of word lines comprises a first word line arranged on a first sidewall of an opening of each mold insulating layer, with the channel layer and the ferroelectric layer arranged therebetween, and
wherein a second word line arranged on a second sidewall of the opening of the mold insulating layer, with the channel layer and the ferroelectric layer arranged therebetween.

9. The semiconductor device of claim 1, further comprising spacers arranged on the plurality of word lines,
wherein one or more of the plurality of word lines have a vertical cross-section of L shape.

10. The semiconductor device of claim 1,
wherein the base dielectric layer comprises a ferroelectric material having a chemical formula of HfₓM₁₋ₓO_{y} (0<x<1, 2<y≤4, and M includes at least one of Zr, Si, Al, Y, Gd, La, Sc, and Sr), and the ferroelectric material has an orthorhombic crystal structure.

11. The semiconductor device of claim 1,
wherein a thickness of the ferroelectric material exceeds 0 nm and is equal to or less than about 10 nm, and a diameter of the nano particle exceeds 0 nm and equal to or less than about two thirds of the thickness of the ferroelectric material.

12. The semiconductor device of claim 1,
wherein the channel layer comprises at least one of polysilicon, silicon-germanium, InGaZnOₓ (IGZO), Sn-doped IGZO, W-doped InOₓ (IWO), CuS₂, CuSe₂, WSe₂, InZnOₓ (IZO), ZnSnOₓ (ZTO), YZnOₓ (YZO), MoS₂, MoSe₂, and WS₂.

13. A semiconductor device comprising:
a plurality of bit lines arranged on a substrate and extending in a first horizontal direction;
a plurality of mold insulating layers respectively arranged on the plurality of bit lines, one or more of the plurality of mold insulating layers including a plurality of openings extending in a second horizontal direction substantially vertical to the first horizontal direction;
a first cell transistor arranged on a first sidewall of an opening of the plurality of openings; and
a second cell transistor arranged on a second sidewall of the opening,
wherein the first cell transistor comprises:
a first channel layer arranged on the first sidewall of the opening;
a first ferroelectric material arranged on the first channel layer; and
a first word line arranged on the first ferroelectric material and extending in the second horizontal direction,
wherein the second cell transistor comprises:
a second channel layer arranged on the second sidewall of the opening;
a second ferroelectric material arranged on the second channel layer; and
a second word line arranged on the second ferroelectric material and extending in the second horizontal direction,
wherein the first ferroelectric material and the second ferroelectric material each comprises a base dielectric layer and nanoparticles, the nanoparticles having a core-shell structure including a core and a shell and the nanoparticles distributed and arranged in the base dielectric layer,
wherein the core comprises a center of the nano particle, and
wherein the shell comprises a portion except for the core in the nano particle and at least partially surrounds the core.

14. The semiconductor device of claim 13, further comprising a horizontal connecting unit connected to bottom portions of the first channel layer and the second channel layer and extending in the first horizontal direction.

15. The semiconductor device of claim 13,
wherein the nano particle and the core have a substantially spherical shape.

16. The semiconductor device of claim 13,
wherein the shell comprises a metal oxide having a greater bandgap energy than a material constituting the base dielectric layer.

17. The semiconductor device of claim 13,
wherein the base dielectric layer comprises a ferroelectric material having a chemical formula of HfₓM₁₋ₓO_{y} (0<x<1, 2<y≤4, and M includes at least one of Zr, Si, Al, Y, Gd, La, Sc, and Sr), and the ferroelectric material has an orthorhombic crystal structure.

18. A semiconductor device comprising:
a bit line arranged on a substrate and extending in a first horizontal direction;
a channel layer including a first vertical extension portion arranged on the bit line and extending in a vertical direction substantially vertical to an upper surface of the substrate, a second vertical extension portion spaced apart from the first vertical extension portion and extending in the vertical direction, and a horizontal extension portion connected to bottom portions of the first vertical extension portion and the second vertical extension portion and extending in the first horizontal direction;
a gate insulating layer arranged on the first vertical extension portion and the second vertical extension portion;
a ferroelectric layer arranged on the gate insulating layer; and
a plurality of word lines arranged on the ferroelectric layer and extending in a second horizontal direction substantially vertical to the first horizontal direction, the plurality of word lines including first word lines arranged on the first vertical extension portion with the gate insulating layer and the ferroelectric layer arranged therebetween and second word lines arranged on the second vertical extension portion with the gate insulating layer and the ferroelectric layer arranged therebetween,
wherein the ferroelectric layer comprises a base dielectric layer and a nanoparticle, the nanoparticle dispersed and arranged in the base dielectric layer,
the nanoparticle has a core-shell structure,
the nanoparticle and the core have a spherical shape having a substantially concentric cross-section, and
the shell includes a portion corresponding to the nanoparticle except for the core and at least partially surrounds the core.

19. The semiconductor device of claim 18, wherein the base dielectric layer comprises a ferroelectric material having a chemical formula of HfₓM₁₋ₓO_{y} (0<x<1, 2<y≤4, and M includes at least one of Zr, Si, Al, Y, Gd, La, Sc, and Sr), and
the ferroelectric material has an orthorhombic crystal structure.

20. The semiconductor device of claim 19,
wherein the shell comprises a metal oxide having a greater bandgap energy than the ferroelectric material.
